(19) United States
(12) Patent Application Publication
(10) Pub. No.: US 2004/0150489 A1
(43) Pub. Date: Aug. 5, 2004

(54) On-carrier impedance transform network

(75) Inventors: Timothy Allan Driver, Mesa, AZ (US); Khalid Paul Shallal, Chandler, AZ (US); Erin Leason Spivey, Chandler, AZ (US)

Correspondence Address: Law Offices of Boris G. Tankhilevich, Suite A, 536 N. Civic Drive, Walnut Creek, CA, 94597, US

(73) Assignee: SIRENZA MICRODEVICES, INC

(21) Appl. No.: 10/360,107

(22) Filed: Feb. 5, 2003

(51) Int. Cl. H03H 7/38

(52) U.S. Cl. 333/32; 333/33

(57) ABSTRACT

An RF circuit comprising: (a) an input low pass impedance transform network having an input and an output; (2)an input high pass impedance transform network having an input and an output; (3) an output high pass impedance transform network having an input and an output; and (4) an output low pass impedance transform network having an input and an output. The RF circuit includes an RF transistor coupled to the input high pass impedance transform network and to the output high pass impedance transform network. An input impedance of the RF transistor is matched to an input impedance of the RF circuit, wherein an output impedance of the RF transistor is matched to an output impedance of the RF circuit.

### BACKGROUND OF THE INVENTION

1. Field of the Invention

The present invention pertains generally to the field of high power, radio frequency transistors, and more specifically to presenting optimal impedances to an LDMOS power transistor device to insure best possible performance.

2. Background

Radio frequency (RF) amplifiers have become widely used in wireless TO communication systems. These wireless communication systems place stringent demands on the amplifiers. Such amplifiers are often manufactured using LDMOS power transistors because they are able to meet the demanding system requirements for power, linearity and efficiency.

LDMOS RF power transistors of the prior art have been comprised of plurality of electrodes formed on a silicon die. These electrodes are coupled to a plurality of interdigitated transistors in a parallel fashion. The silicon die is disposed atop a metal substrate, which provides ground reference and thermal heat sink. This matter of disposition is known as eutectic die attach. This metallic substrate is in turn attached to the amplifiers ground reference and heat sink.

For a transistor to be useful in this context, it is necessary to couple its inputs and outputs to an amplifier. An amplifier is a circuit which provides both bias and proper terminating impedance connections to a transistor. When done properly, the amplifier has the ability to provide RF power gain. Normally this coupling is achieved by the use of two groups of plurality of wire interconnects. One group of these wires connects the input plurality of transistor electrodes (gate) to the amplifiers gate contact. The other group of these wires connects the output plurality of transistor electrodes (drain) to the amplifiers drain contact.

The impedance matching of the transistor is crucial to proper operation of the amplifier device, especially at high operating frequencies. Impedance levels at the end of gate wire interconnect plane are very low (sub 1 Ω). Impedance levels at the end of drain wire interconnect plane are also very low.

Transform networks transform these low impedances up to higher system level impedances (typically 50 Ω). These transform networks usually comprise multiple stages.

The prior art matching topologies typically employ a total of 4 transform networks to transform the low transistor impedance up to the high (typically 50 Ω) system impedance. The best matching topologies of prior art have low loss and low quality factor (Q).

Indeed, the prior art LDMOS RF power transistor circuitry that includes low loss matching topologies insure high efficiency of the LDMOS RF power transistor and the reduction in the overall system cost. For example, the prior art LDMOS RF power transistor circuitry including contiguous ground planes has low loss due to confinement of circulating ground currents.

In addition, the low Q's matching topologies insure maximum bandwidth, which maximizes data transfer by maximizing the number of data channels that can be passed through said transistor.

However, the prior art matching topologies have used a low pass transform network as the first stage of matching. This has not been the optimal topology from a Q standpoint.

What is needed is to employ a high pass input transform network as the first stage at the input of the transistor, and to employ a high pass output transform network at the output of the transistor (all on a contiguous ground plane) in order to optimize the matching of input and output impedances of the transistor to the outside circuitry.

### SUMMARY OF THE INVENTION

To address the shortcomings of the available art, the present invention provides an RF circuitry configured to optimally match the input and output impedances of the RF transistor.

One aspect of the present invention is directed to an RF circuit configured to optimally match the input and output impedances of an RF transistor. In one embodiment of the present invention, the RF circuit comprises: (1) an input low pass impedance transform network (IL_PITN) having an input and an output; (2) an input high pass impedance transform network (IH_PITN) having an input and an output; (3) an output high pass impedance transform network (OH_PITN) having an input and an output; and (4) an output low pass impedance transform network (OL_PITN) having an input and an output.

In another embodiment of the present invention, the RF circuit configured to optimally match the input and output impedances of the RF transistor comprises: (1) an input low pass impedance transform network (IL_PITN) having an input and an output; (2) an input high pass impedance transform network (IH_PITN) having an input and an output; and (3) an output high pass impedance transform network (OH_PITN) having an input and an output.

In one more embodiment of the present invention, the RF circuit comprises: (1) an input high pass impedance transform network (IH_PITN) having an input and an output; (2) an output high pass impedance transform network (OH_PITN) having an input and an output; and (3) an output low pass impedance transform network (OL_PITN) having an input and an output.

In one additional embodiment of the present invention, the RF circuit comprises: (1) an input high pass impedance transform network (IH_PITN) having an input and an output; and (2) an output high pass impedance transform network (OH_PITN) having an input and an output.

In one embodiment, the input of the IH_PITN is connected to a first junction, and the output of the IH_PITN is connected to a second junction; the input of the OH_PITN is connected to a third junction; the output of the OH_PITN is connected to a fourth junction. In this embodiment, the RF circuit includes an RF transistor coupled to the second junction and coupled to the third junction, wherein the input impedance of the RF transistor is matched to the input impedance of the RF circuit, and wherein the output impedance of the RF transistor is matched to the output impedance of the RF circuit.

In one embodiment of the present invention, the IL_PITN, and /or OL_PITN comprises a low pass circuit further comprising: at least one series inductor member; and/or at least one shunt capacitor member.

In one embodiment of the present invention, the IH_PITN and/or OH_PITN comprises a high pass circuit further comprising: at least one series capacitor member; and/or at least one shunt inductor member.

A shunt capacitor member and /or a series capacitor member can include: a single layer capacitor; a multiple layer capacitor; an interdigitated capacitor; a printed transmission line including an effective capacitive impedance; and/or a member including an effective capacitive impedance.

A series inductor member and/or a shunt inductor member can include: a bond wire; a spiral inductor; a ribbon wire; a coil wire inductor; a printed transmission line including an effective, inductive impedance; and/or a member including an effective inductive impedance.

Another aspect of the present invention is directed to a method for optimizing an on-carrier impedance of an RF circuit including an RF transistor. In one embodiment, the method of the present invention comprises the following steps: matching an input impedance of the RF transistor to an input impedance of the RF circuit; and matching an output impedance of the RF transistor to an output impedance of the RF circuit.

### BRIEF DESCRIPTION OF THE DRAWINGS

The aforementioned advantages of the present invention as well as additional advantages thereof will be more clearly understood hereinafter as a result of a detailed description of a preferred embodiment of the invention when taken in conjunction with the following drawings.

FIG. 1 depicts a prior art matching topology (along with the transistor and wire interconnects) that employs a total of 4 transform networks to transform the low transistor impedance up to the high (50 Ω) system impedance.

FIG. 2 shows an optimum matching topology of the present invention including a high pass transform network as the first stage for both the input and output of the transistor, all on a contiguous ground plane, as well as a low pass second stage input and output transform networks.

FIG. 3A illustrates the Smith chart corresponding to the optimum transform network topology of FIG. 2 comprising a concatenated output transform network topology High Pass-Low Pass (HL).

FIG. 3B shows the Smith chart corresponding to the optimum transform network topology of FIG. 2 comprising a concatenated input transform network topology Low Pass-High Pass (LH).

FIG. 4 depicts an optimum matching topology of the present invention including a high pass transform network as the first stage for both the input and output of the transistor, all on a contiguous ground plane, as well as a low pass second stage input transform network.

FIG. 5 illustrates the Smith chart corresponding to the optimum transform network topology of FIG. 4 comprising an output High Pass transform network topology.

FIG. 6 shows an optimum matching topology of the present invention including a high pass transform network as the first stage for both the input and output of the transistor, all on a contiguous ground plane, as well as a low pass second stage output transform network.

FIG. 7 depicts an optimum matching topology of the present invention including a high pass transform network as the first stage for both the input and output of the transistor, all on a contiguous ground plane.

FIG. 8A is an example of specific implementation of matching topology of FIG. 2 including a high pass transform network as the first stage for both the input and output of the transistor, all on a contiguous ground plane, as well as a low pass second stage input and output transform networks.

FIG. 8B is a top view of metal oxide semiconductor capacitors (MOSCAPs), transistor and wire bonds using the optimal impedance matching topology (Low Pass-High Pass input, as well as High Pass-Low Pass output) based on carrier.

FIG. 9 depicts a side view of MOSCAPs, transistor and wire bonds of FIG. 8 that is based on a carrier.

### DETAILED DESCRIPTION OF THE PREFERRED AND ALTERNATIVE EMBODIMENTS

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

The prior art LDMOS RF power transistors have been comprised of plurality of electrodes formed on a silicon die. These electrodes are coupled to a plurality of interdigitated transistors in a parallel fashion. In the prior art eutectic die attach embodiment, the silicon die is disposed atop a metal substrate, which provides ground reference and thermal heat sink. The metallic substrate is also attached to the amplifiers ground reference and heat sink.

In this prior art embodiment, a transistor is coupled to an amplifier, which provides both bias and proper terminating impedance connections to the transistor. Typically, the transistor-amplifier coupling is enabled by utilizing two groups of pluralities of wire interconnects. One group of these wires connects the input plurality of transistor electrodes (gate) to the amplifiers gate contact. The other group of these wires connects the output plurality of transistor electrodes (drain) to the amplifiers drain contact. The amplifier usually provides RF power gain.

Impedance levels at the end of gate wire interconnect plane are very low (sub 1 Ω). Impedance levels at the end of drain wire interconnect plane are also very low. On the other hand, the external circuitry typically includes higher level impedances (approximately 50 Ω). Therefore, the impedance matching of the transistor to the outside circuitry is crucial to proper operation of the amplifier device, especially at high operating frequencies. The prior art impedance matching is usually implemented by using transform networks that typically comprise of multiple stages.

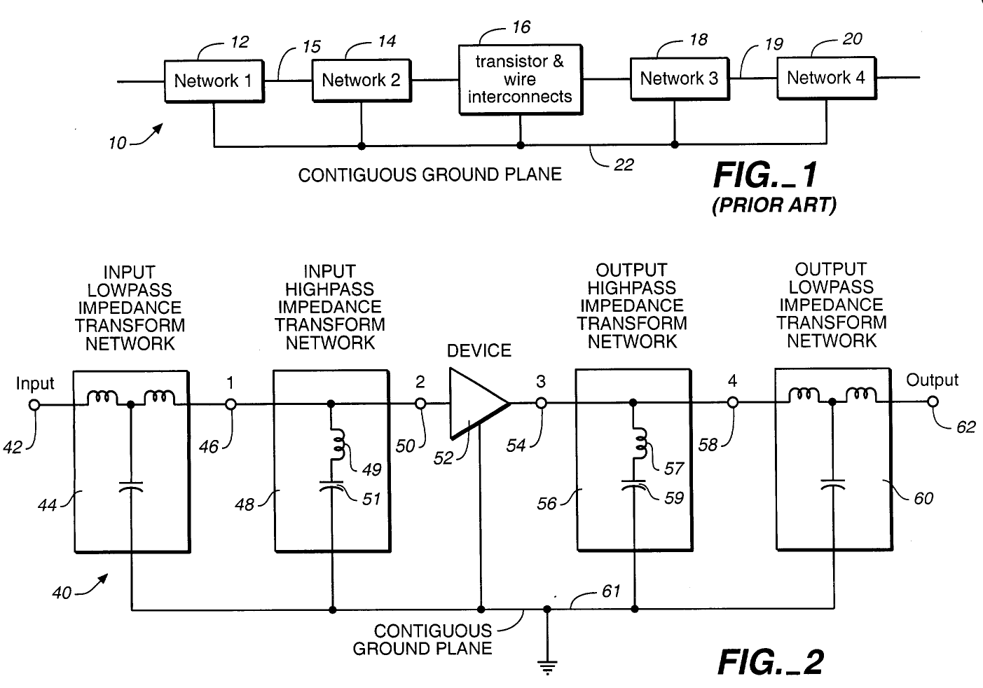

FIG. 1 depicts a prior art matching topology 10 (along with the transistor and wire interconnects) that employ a total of 4 transform networks to transform the low transistor impedance up to the high (50 Ω) system impedance.

As shown in FIG. 1, the network #2 14, the transistor (and wire interconnects) 16 and the network #3 18 are mounted on a single contiguous ground plane 22. The network #2 14 matches the low transistor input impedance with an intermediate impedance value. The network #2 is typically comprised of a combination of metal oxide semiconductor capacitors (MOSCAPs) and wire interconnects. The network #3 18 matches the low transistor output impedance with an intermediate impedance value, and is also typically comprised of a combination of MOSCAPs and wire interconnects. The network #1 12 matches the intermediate input impedance value with the system impedance (50 Ω), and is usually comprised of a combination of printed metal lines on dielectric substrate and lumped components. The network #1 12 is coupled to network #2 14 via an electrical connection 15. Similarly, the network #4 20 matches the intermediate output impedance with the system impedance (50 Ω). The network #4 20 is comprised of a combination of printed metal lines on dielectric substrate and lumped components. The network #4 20 is coupled to the network #3 18 via an electrical connection 19.

The prior art matching topology 10 (of FIG. 1) typically employs a low pass network for network #2 14, and a high pass network for network #3 18. Network #1 12 and network #4 20 are typically low pass networks. However, the prior art matching topology 10 is not optimum.

Indeed, the optimum matching topologies should have the lowest possible loss and the lowest possible quality factor (Q). The matching topology having the lowest possible loss generally has highest efficiency and the reduced overall system cost. The prior art matching topology 10 (of FIG. 1) utilizes the contiguous ground plane 22 which is consistent with the lowest loss matching topology due to confinement of circulating ground currents.

On the other hand, the matching topology having the lowest possible Q should include the maximum possible bandwidth, because by maximizing the number of data channels that is passed through the transistor, the data transfer is also maximized. In terms of lowest possible Q, the prior art topology 10 (of FIG. 1) is not optimized.

Indeed, because the transistor's output impedance at RF frequency is capacitive, the optimum transform network that matches the transistor's output should have a high pass structure (an inductance in parallel (shunt) with the transistor's output) because it has the lowest possible Q matching topology.

The transistor's input impedance at RF frequency is also capacitive. Similarly, the optimum transform network that matches the transistor's input should also have a high pass structure (an inductance in parallel (shunt) with the transistor's input) because it has the lowest possible Q matching topology.

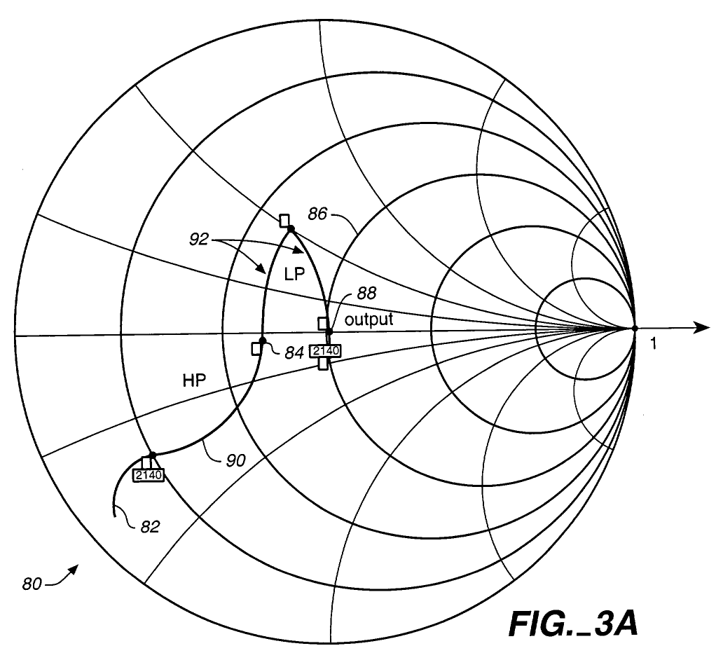

In one embodiment of the present invention, FIG. 2 shows the RF circuit 40 that includes the optimum matching topology configured to optimally match the input impedances of an RF transistor 52 to the input impedance of the outside circuitry, and configured to optimally match the output impedances of an RF transistor 52 to the output impedance of the outside circuitry. The outside circuitry includes input 42 and output 62. In one embodiment of the present invention, the matching topology 40 (of FIG. 2) includes: (1) an input low pass impedance transform network (IL_PITN) 44 having an input and an output; (2) an input high pass impedance transform network (IH_PITN) 48 having an input and an output; (3) an output high pass impedance transform network (OH_PITN) 56 having an input and an output; and (4) an output low pass impedance transform network (OL_PITN) 60 having an input and an output.

In one embodiment, the input of the IH_PITN 48 is connected to a first junction 46, and the output of the IH_PITN is connected to a second junction 50. In this embodiment, the input of the OH_PITN 56 is connected to a third junction 54, and the output of the OH_PITN is connected to a fourth junction 58. In this embodiment, the RF circuit 40 includes an RF transistor 52 coupled to the second junction 50 and coupled to the third junction 54. In this embodiment, as it is shown below, the input impedance of the RF transistor 52 is matched to the input impedance of the RF circuit 40, and the output impedance of the RF transistor 52 is matched to the output impedance of the RF circuit 40.

Thus, the optimum matching topology 40 (of FIG. 2) includes the high pass impedance transform network IH_PITN 48 as the first stage at the input of the transistor 52,the high pass impedance transform network OH_PITN 56 as the first stage at the output of the transistor 52 (all on contiguous ground plane 61, as shown in FIG. 2), as well as the low pass impedance transform network IL_PITN 44 as the second stage at the input of the transistor 52, and the low pass impedance transform network OL_PITN 60 at the output of the transistor 52.

Basically the Smith Chart© (the trademark of Analog Instruments) is a transformation between an impedance Z and the reflection coefficient Γ of a transmission line, taking the form of:

∥Γ∥ [symbol] φ={Z−Z₀/Z+Z₀}; (1)

where Z₀ represents a reference impedance whose value depends on how the Smith chart is to be used.

Let

Z/Z₀=z=r+jx; (2)

and

∥Γ∥ [symbol] φ=U+jV; (3)

where j is an imaginary one, and both r and x are measured in Ω.

Eq. (1) has a solution in terms of (U, V, r) (for circuits comprising of elements having only real impedances):

(U−r/(r+1))²+V²=(1/(r+1))². (4)

Eq. (4) represents the equation for a family of circles whose centers are at:

[symbol]

U=r/(r+1);

[symbol]

V=0 (5)

and whose radii are:

1/(r+1). (6)

There is another solution for Equation (1) in terms of (U, V, x)(for circuits comprising of elements having only imaginary impedances):

(U−1)²+(V−(1/x))²=(1/x)²; (7)

which is the equation for a family of circles whose centers are at:

[symbol]

U=1;

[symbol]

V=1/x; (8)

and whose radii are:

1/x. (9)

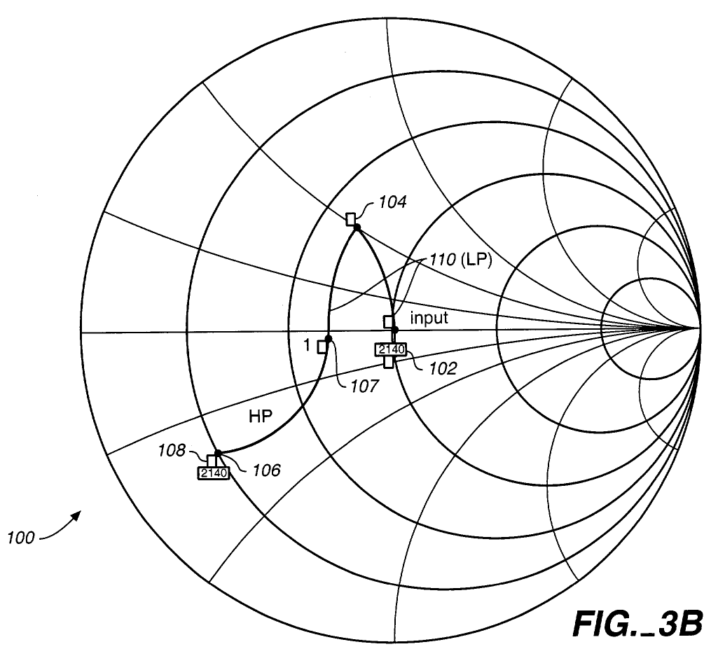

When two sets of circles that follow Eq. (5) and Eq. (8) are combined to form a Smith Chart© (80 of FIG. 3), the U and V axes are discarded, a linear scale for ∥Γ∥ is provided, and positive and negative angles [symbol] φ are marked around the outside of the r=0 circle.

FIG. 3A represents the Smith Chart© 80 for circuitry comprising of elements having both real and imaginary impedances. Using the Smith Chart© 80, it is easy to understand why, in one embodiment of the present invention, the transform network topology 40 (of FIG. 2) is an optimum one. Indeed, the transform network topology 40 (of FIG. 2) includes the concatenated output transform network topology High Pass-Low Pass (HL) further including the high pass output impedance transform network OH_PITN 56 (of FIG. 2) as the first stage at the output of the transistor 52 (of FIG. 2), and the low pass output impedance transform network OL_PITN 60 (of FIG. 2) at the second stage at the output of the transistor 52 (of FIG. 2). In one embodiment of the present invention, the output high pass (High Pass)-low pass (Low Pass) network matching topology is used to match the low impedance at the output of the transistor (52 of FIG. 2) corresponding to point 82 at the Smith Chart© 80 (of FIG. 3A), to the high impedance at the output 62 of the RF circuit (40 of FIG. 2) that corresponds to the point 88 at the Smith Chart© 80 (of FIG. 3A).

More specifically, the impedance of the high pass output impedance transform network OH_PITN 56 (of FIG. 2) at the output of the transistor 52 (of FIG. 2) is represented at the Smith Chart© 80 (of FIG. 3A) by the element High Pass 90 that connects two points: point 82 corresponding to the impedance at the output of the transistor and point 84 corresponding to the intermediate impedance at the output 58 of the OH_PITN 56 (of FIG. 2). The next element Low Pass 92 connects two points: point 84 corresponding to the intermediate impedance at the output 58 of the OH_PITN 56 (of FIG. 2) and point 88 corresponding to the output impedance at the output 62 of the RF circuit (62 of FIG. 2). Thus, the usage of concatenated elements High Pass-Low Pass (90-92) allows one to optimize matching the low impedance (typically 1 Ω) at the output of the transistor 52 (of FIG. 2) to the impedance (typically 50 Ω) at the output 62 of the RF circuitry 40 (of FIG. 2). The invention presented in this patent application approach allows one to obtain the RF circuitry that uses only two transform networks to match the low output impedance of the transistor to the output impedance of the RF circuitry (50 Ω), thus reducing the total circuitry required, and increasing the total system reliability. The RF circuitry (40 of FIG. 2) is also characterized by low Q.

FIG. 3B shows the Smith Charts© 100 corresponding to the optimum transform network topology of FIG. 2 comprising a concatenated input transform network topology Low Pass-High Pass (LH). Indeed, the transform network topology 40 (of FIG. 2) includes the concatenated input transform network topology Low Pass-High Pass (LH) further including the low pass input impedance transform network IL_PITN 44 (of FIG. 2) and the high pass input impedance transform network IH_PITN 48 (of FIG. 2). In one embodiment of the present invention, the input Low pass-High Pass (LH) network matching topology is used to match the low impedance at the input of the transistor (52 of FIG. 2) corresponding to point 106 at the Smith Chart© 100 (of FIG. 3B), to the high impedance at the input 42 of the RF circuit (40 of FIG. 2) that corresponds to the point 102 at the Smith Chart© 100 (of FIG. 3B).

More specifically, the impedance of the high pass input impedance transform network IH_PITN 48 (of FIG. 2) at the input of the transistor 52 (of FIG. 2) is represented at the Smith chart 100 (of FIG. 3B) by the element High Pass 108 that connects two points: point 106 corresponding to the impedance at the input of the transistor 52 and point 107 corresponding to the intermediate impedance at the input 46 of the IH_PITN 48 (of FIG. 2). The next element Low Pass 110 connects two points: point 107 corresponding to the intermediate impedance at the input 46 of the IH_PITN 48 (of FIG. 2) and point 102 corresponding to the input impedance at the input 42 of the RF circuit (40 of FIG. 2). Thus, the usage of concatenated elements Low Pass-High Pass (110-108) allows one to optimize matching the low impedance (typically 1 Ω) at the input of the transistor (of FIG. 2) to the impedance (typically 50 Ω) at the input 42 of the RF circuitry 40 (of FIG. 2). The invention presented in this patent application approach allows one to obtain the RF circuitry that uses only two transform networks to match the low input impedance of the transistor to the input impedance of the RF circuitry (50 Ω), thus reducing the total circuitry required, and increasing the total system reliability. The RF circuitry (40 of FIG. 2) is also characterized by low Q.

Referring still to FIG. 2, in one embodiment of the present invention, the input high pass transform network IH_PITN 48 comprises an inductor-capacitor series structure further comprising an inductor 49 concatenated with a capacitor 51 (a series capacitor). In one embodiment, the inductor-capacitor series structure is placed in shunt with the device 52.

In one embodiment of the present invention, the output high pass transform network OH_PITN 56 further comprises an inductor-capacitor series structure further comprising an inductor 57 concatenated with a capacitor 59 (a series capacitor). In one embodiment, the inductor-capacitor series structure is placed in shunt with the device 52. The series capacitor 51 is not required for the input high pass -transform network 48. On the other hand, the series capacitor 59 is always required for the output high pass transform network 56 to implement a DC blocking function.

In one embodiment of the present invention, the input low pass transform network IL_PITN 44 (of FIG. 2) comprises a low pass circuit further comprising: at least one series inductor member; and/or at least one shunt capacitor member. In one embodiment of the present invention, the output low pass transform network OL_PITN 60 (of FIG. 2) comprises a low pass circuit further comprising: at least one series inductor member; and/or at least one shunt capacitor member.

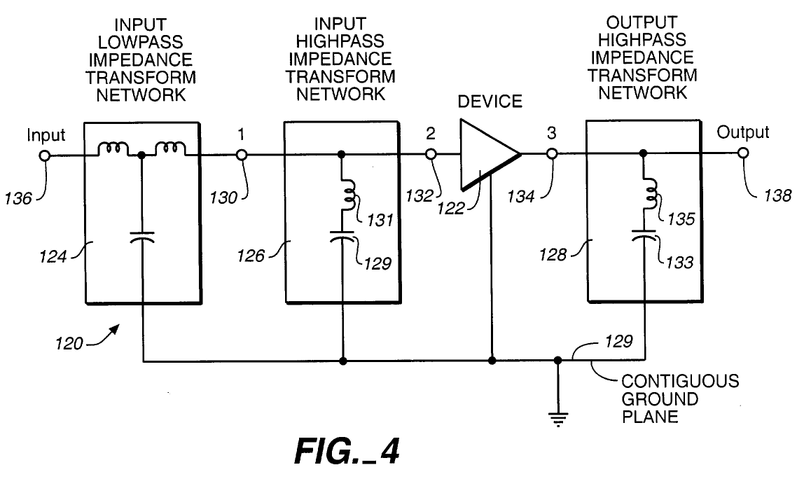

In one embodiment of the present invention, as depicted in FIG. 4, the RF circuit 120 configured to optimally match the input and output impedances of the RF transistor 122 comprises: (1) an input low pass impedance transform network (IL_PITN) 124 having an input and an output; (2) an input high pass impedance transform network (IH_PITN) 126 having an input and an output; and (3) an output high pass impedance transform network (OH_PITN) 128 having an input and an output.

In one embodiment, the input of the IH_PITN 126 is connected to the first junction 130, and the output of the IH_PITN 126 is connected to the second junction 132. In this embodiment, the input of the OH_PITN 128 is connected to a third junction 134, and the output of the OH_PITN 128 is connected to the output 138 of the RF circuit 120. In this embodiment, the RF circuit 120 includes the RF transistor 122 coupled to the second junction 132 and coupled to the third junction 134. In this embodiment, as it is shown below, the input impedance of the RF transistor 122 is matched to the input impedance of the RF circuit 120, and the output impedance of the RF transistor 122 is matched to the output impedance of the RF circuit 120.

Thus, FIG. 4 depicts an optimum matching topology 120 of the present invention including a high pass input transform network IH_PITN 126 as the first stage for the input of the RF transistor 122, including a high pass output transform network OH_PITN 128 as the first stage for the output of the transistor 122 (all on contiguous ground plane 129), as well as a low pass second stage input transform network IL_PITN 124.

The implementation of the optimum matching of the input impedance of the transistor 122 to the input impedance of the RF circuitry using the input matching topology 120 of FIG. 4 is substantially the same as the implementation of optimum matching of the input impedance of the transistor 52 to the input of the RF circuitry by using the input matching topology 40 of FIG. 2. It was fully discussed above, and is incorporated herein to avoid redundancy.

On the other hand, the implementation of the optimum matching of the output impedance of the transistor 122 to the output impedance of the RF circuitry using the output matching topology 120 of FIG. 4 is disclosed below using the Smith Chart© 140 of FIG. 5.

FIG. 5 illustrates the Smith Chart© 140 corresponding to the optimum output impedance transform network topology of FIG. 4 120 further including the high pass output impedance transform network OH_PITN 128. In one embodiment of the present invention, the output high pass (High Pass) network matching topology is used to match the low impedance at the output of the transistor (122 of FIG. 4) corresponding to point 146 at the Smith Chart© 140 (of FIG. 5), to the high impedance at the output 138 of the RF circuit (120 of FIG. 4) that corresponds to the point 147 at the Smith Chart© 140 (of FIG. 5).

In one embodiment of the present invention, the impedance of the high pass output impedance transform network OH_PITN 128 (of FIG. 4) at the output of the transistor 122 (of FIG. 4) is represented at the Smith Charts© 140 (of FIG. 5) by a single High Pass element 142 that connects two points: point 146 corresponding to the impedance at the output of the transistor and point 147 corresponding to the output impedance at the output 138 of the RF circuit (120 of FIG. 4). Thus, the usage of a High Pass element 142 allows one to optimize matching the low impedance (typically 1 Ω) at the output of the transistor 122 (of FIG. 4) to the impedance (typically 50 Ω) at the output 138 of the RF circuitry 120 (of FIG. 4).

Referring still to FIG. 4, in one embodiment of the present invention, the input high pass transform network IH_PITN 126 further comprises an inductor-capacitor series structure further comprising an inductor 131 concatenated with a capacitor 129 (a series capacitor). In one embodiment, the inductor-capacitor series structure is placed in shunt with the device 122.

Referring still to FIG. 4, in one embodiment of the present invention, the output high pass transform network OH_PITN 126 further comprises an inductor-capacitor series structure further comprising an inductor 135 concatenated with a capacitor 133 (a series capacitor). In one embodiment, the inductor-capacitor series structure is placed in shunt with the device 122. The series capacitor 131 is not required for the input high pass transform network 412. On the other hand, the series capacitor 133 is always required for the output high pass transform network 128 to implement a DC blocking function.

Referring still to FIG. 4, in one embodiment of the present invention, the input low pass transform network IL_PITN 124 further comprises at least one series inductor member; and/or at least one shunt capacitor member.

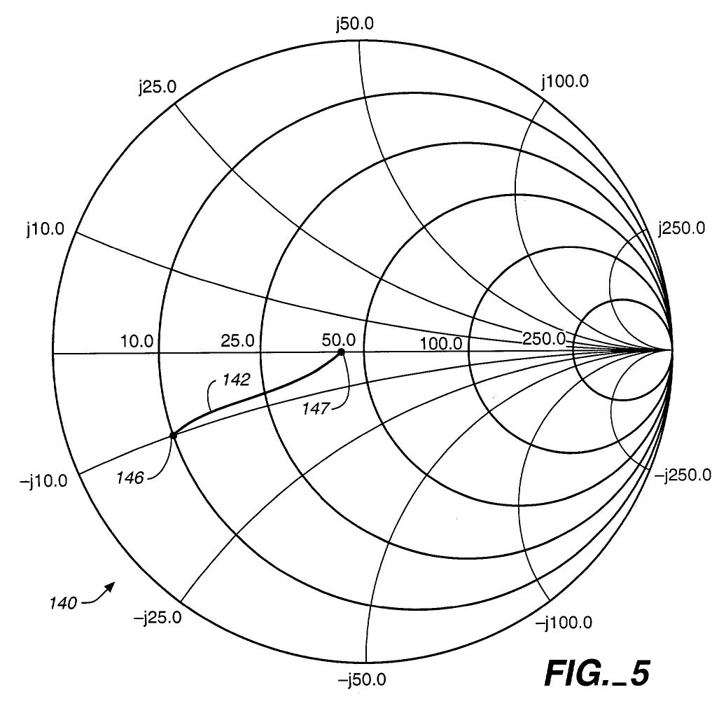

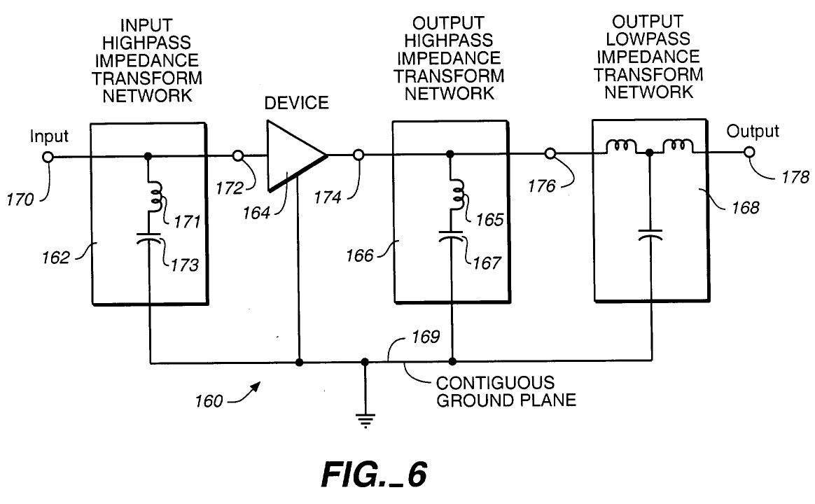

In one embodiment of the present invention, as shown in FIG. 6, the RF circuit 160 configured to optimally match the input and output impedances of the RF transistor 164 comprises: an input high pass impedance transform network (IH_PITN) 162 having an input and an output; (2) an output high pass impedance transform network (OH_PITN) 166 having an input and an output; and (3) an output low pass impedance transform network (OL_PITN) 168 having an input and an output.

Referring still to FIG. 6, in one embodiment, the input of the IH_PITN 162 is connected to the input 170 of the RF circuitry 160, and the output of the IH_PITN 162 is connected to the first junction 172. In this embodiment, the input of the OH_PITN 166 is connected to the second junction 174, and the output of the OH_PITN 166 is connected to the third junction 176. In this embodiment, the RF circuit 160 includes the RF transistor 164 coupled to the first junction 172 and coupled to the second junction 174. In this embodiment, as it is shown below, the input impedance of the RF transistor 164 is matched to the input impedance of the RF circuit 160, and the output impedance of the RF transistor 164 is matched to the output impedance of the RF circuit 160.

Thus, FIG. 6 depicts an optimum matching topology 160 of the present invention including a high pass input transform network IH_PITN 162 as the first stage for the input of the RF transistor 164, including a high pass output transform network OH_PITN 166 as the first stage for the output of the transistor 164 (all on a contiguous ground plane 169), as well as a low pass second stage output transform network OL_PITN 168.

Referring still to FIG. 6, the implementation of the optimum matching of the output impedance of the transistor 164 to the output impedance of the RF circuitry using the output matching topology 160 was fully discussed above, and is incorporated herein to avoid redundancy, because it is substantially the same as the implementation of optimum matching of the output impedance of the transistor 52 to the output of the RF circuitry by using the output matching topology 40 of FIG. 2.

Referring still to FIG. 6, the implementation of the optimum matching of the input impedance of the transistor 164 to the input impedance of the RF circuitry using the input matching topology 160 is substantially the same and therefore incorporates (to avoid redundancy) the discussion of the optimum matching of the output impedance of the transistor 122 to the output impedance of the RF circuitry using the output matching topology 120 of FIG. 4. It was explained above by using the Smith Chart© 140 of FIG. 5.

Referring still to FIG. 6, in one embodiment of the present invention, the input high pass transform network IH_PITN 162 comprises an inductor-capacitor series structure further comprising an inductor 171 concatenated with a capacitor 173 (a series capacitor). In one embodiment, the inductor-capacitor series structure is placed in shunt with the device 164.

Referring still to FIG. 6, in one embodiment of the present invention, the output high pass transform network OH_PITN 166 further comprises an inductor-capacitor series structure further comprising an inductor 165 concatenated with a capacitor 167 (a series capacitor). In one embodiment, the inductor-capacitor series structure is placed in shunt with the device 164. The series capacitor 167 is not required for the input high pass transform network 162. On the other hand, the series capacitor 167 is always required for the output high pass transform network 166 to implement a DC blocking function.

In one embodiment of the present invention, the output low pass transform network OL_PITN 168 (of FIG. 6) comprises a low pass circuit further comprising: at least one series inductor member; and/or at least one shunt capacitor member.

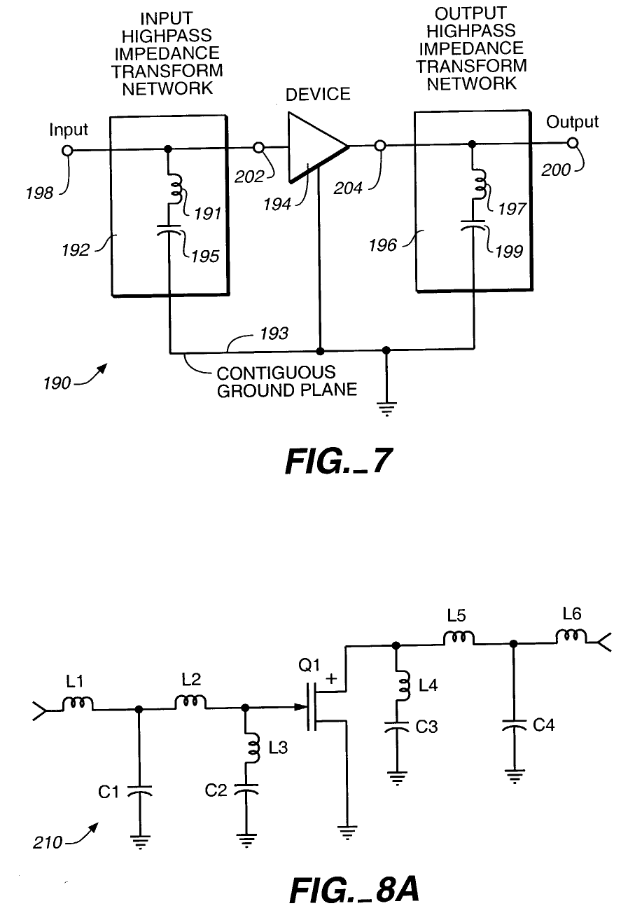

In one embodiment of the present invention, as shown in FIG. 7, the RF circuit 190 configured to optimally match the input and output impedances of the RF transistor 194 comprises: an input high pass impedance transform network (IH_PITN) 192 having an input and an output; and (2) an output high pass impedance transform network (OH_PITN) 196 having an input and an output.

Referring still to FIG. 7, in one embodiment, the input of the IH_PITN 192 is connected to the input 198 of the RF circuitry 190, and the output of the IH_PITN 192 is connected to the first junction 202. In this embodiment, the input of the OH_PITN 196 is connected to the second junction 204, and the output of the OH_PITN 196 is connected to the output 200 of the RF circuitry 190. In this embodiment, as it is shown below, the input impedance of the RF transistor 194 is matched to the input impedance of the RF circuit 190, and the output impedance of the RF transistor 194 is matched to the output impedance of the RF circuit 190.

FIG. 7 depicts an optimum matching topology 190 of the present invention including a high pass input transform network IH_PITN 192 at the input of the RF transistor 194, and including a high pass output transform network OH_PITN 196 at the output of the transistor 194 (all on a contiguous ground plane 193).

Referring still to FIG. 7, the implementation of the optimum matching of the input impedance of the transistor 194 to the input impedance of the RF circuitry using the input matching topology, as well as the implementation of the optimum matching of the output impedance of the transistor 194 to the output impedance of the RF circuitry using the output matching topology, was fully discussed above, and is incorporated herein to avoid redundancy.

Referring still to FIG. 7, in one embodiment of the present invention, the input high pass transform network IH_PITN 192 comprises an inductor-capacitor series structure further comprising an inductor 191 concatenated with a capacitor 195 (a series capacitor). In one embodiment, the inductor-capacitor series structure is placed in shunt with the device 194.

In one embodiment of the present invention, the output high pass transform network OH_PITN 196 further comprises an inductor-capacitor series structure further comprising an inductor 197 concatenated with a capacitor 199 (a series capacitor). In one embodiment, the inductor-capacitor series structure is placed in shunt with the device 194. The series capacitor 195 is not required for the input high pass transform network 192. On the other hand, the series capacitor 199 is always required for the output high pass transform network 196 to implement a DC blocking function.

A shunt capacitor member and/or a series capacitor member can include: a single layer capacitor; a multiple layer capacitor; an interdigitated capacitor; a printed transmission line including an effective capacitive impedance; and/or a member including an effective capacitive impedance. The person skilled in the art knows how to build a shunt capacitor member and/or a series capacitor member by using a single layer capacitor; a multiple layer capacitor; an interdigitated capacitor; a printed transmission line including an effective capacitive impedance; and/or a member including an effective capacitive impedance.

A series inductor member and/or a shunt inductor member can include: a bond wire; a spiral inductor; a ribbon wire; a coil wire inductor; a printed transmission line including an effective inductive impedance; and/or a member including an effective inductive impedance. The person skilled in the art knows how to build a series inductor member and/or a shunt inductor member by using a bond wire; a spiral inductor; a ribbon wire; a coil wire inductor; a printed transmission line including an effective inductive impedance; and/or a member including an effective inductive impedance.

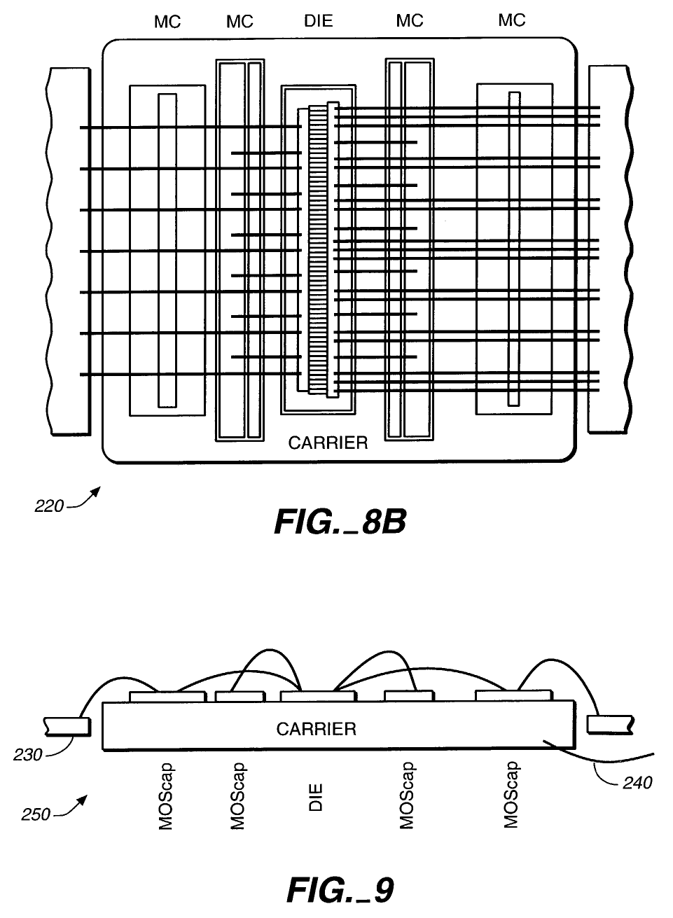

FIG. 8A is an example of specific implementation 210 of matching topology of FIG. 2 including a high pass transform network as the first stage for both the input (L3, C2) and output (L4, C3) of the transistor (Q1), all on a contiguous ground plane, as well as a low pass second stage input (L1, C1, L2) and output (L5, C4, L6) transform networks. L1, L2, L3, L4, L5, and L6 are all constructed of wires bonded to the circuit elements. C2 and C4 are high value capacitors, effectively acting as electrical short circuits at the frequency of operation. Capacitors C2 and C4 are constructed using a low loss implementation of an MOS structure. Capacitors C1 and C4 are MOS capacitors (MOSCAPs) used to optimize the circuit impedance to the desired level. All of the ground connection illustrated are electrically connected to a carrier. This carrier also acts as a thermal conduit to conduct heat away from the components. Capacitors C1 through C4 and the LDMOS transistor are mechanically and electrically attached to the carrier with eutectic alloys.

FIG. 8B depicts a top view of MOSCAPs, transistor, and wire bonds using the optimal impedance matching topology 220 (Low Pass-High Pass input, as well as High Pass-Low Pass output)that was discussed above and constitutes the subject of the present invention.

FIG. 9 depicts a side view 250 of MOSCAPs, transistor, and wire bonds 230 on a carrier 240 using the optimal impedance matching topology (Low Pass-High Pass input, as well as High Pass-Low Pass output) that was discussed above and constitutes the subject of the present invention.

Another aspect of the present invention is directed to a method for optimizing an on-carrier impedance of an RF circuit including an RF transistor. In one embodiment, the method of the present invention (not shown) comprises the following steps: matching an input impedance of the RF transistor to an input impedance of the RF circuit; and matching an output impedance of the RF transistor to an output impedance of the RF circuit.

The foregoing description of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. An RF circuit comprising:
an input low pass impedance transform network (IL_PITN) having an input and an output; said output of said IL_PITN being connected to a first junction;
an input high pass impedance transform network (IH_PITN) having an input and an output; said input of said IH_PITN being connected to said first junction; said output of said IH_PITN being connected to a second junction;
an output high pass impedance transform network (OH_PITN) having an input and an output; said input of said OH_PITN being connected to a third junction; said output of said OH_PITN being connected to a fourth junction;
and
an output low pass impedance transform network (OL_PITN) having an input and an output; said input of said OL_PITN being connected to said fourth junction;
wherein said RF circuit includes an RF transistor coupled to said second junction and coupled to said third junction, and wherein an input impedance of said RF transistor is matched to an input impedance of said RF circuit;
and wherein an output impedance of said RF transistor is matched to an output impedance of said RF circuit.

2. The RF circuit of claim 1, wherein said IL_PITN comprises a low pass circuit further comprising:
at least one series inductor member;
and
at least one shunt capacitor member coupled to said series inductor member.

3. The RF circuit of claim 1, wherein said IL_PITN comprises a low pass circuit further comprising:
at least one series inductor member.

4. The RF circuit of claim 1, wherein said IL_PITN comprises a low pass circuit further comprising:
at least one shunt capacitor member.

5. The RF circuit of claim 1, wherein said OL_PITN comprises a low pass circuit further comprising:
at least one series inductor member; and
at least one shunt capacitor member coupled to said series inductor member.

6. The RF circuit of claim 1, wherein said OL-PITN comprises a low pass circuit further comprising:
at least one series inductor member.

7. The RF circuit of claim 1, wherein said OL_PITN comprises a low pass circuit further comprising:
at least one shunt capacitor member.

8. The RF circuit of claim 1, wherein said IH_PITN comprises a high pass circuit further comprising:
at least one shunt inductor member;
and
at least one series capacitor member coupled to said shunt inductor member.

9. The RF circuit of claim 1, wherein said IH_PITN comprises a high pass passive circuit further comprising:
at least one shunt inductor member.

10. The RF circuit of claim 1, wherein said OH_PITN comprises a high pass circuit further comprising:
at least one shunt inductor member;
and
at least one series capacitor member coupled to said shunt inductor member.

11. The RF circuit of claim 2, wherein said at least one shunt capacitor member further includes:
a single layer capacitor.

12. The RF circuit of claim 2, wherein said at least one shunt capacitor member further includes:
a multiple layer capacitor.

13. The RF circuit of claim 2, wherein said at least one shunt capacitor member further includes:
an interdigitated capacitor.

14. The RF circuit of claim 2, wherein said at least one shunt capacitor member further includes:
a printed transmission line including an effective capacitive impedance.

15. The RF circuit of claim 2, wherein said at least one shunt capacitor member further includes:
a member including an effective capacitive impedance.

16. The RF circuit of claim 8, wherein said at least one series capacitor member further includes:
a single layer capacitor.

17. The RF circuit of claim 8, wherein said at least one series capacitor member further includes:
a multiple layer capacitor.

18. The RF circuit of claim 8, wherein said at least one series capacitor member further includes:
an interdigitated capacitor.

19. The RF circuit of claim 8, wherein said at least one series capacitor member further includes:
a printed transmission line including an effective capacitive impedance.

20. The RF circuit of claim 8, wherein said at least one series capacitor member further includes:
a member including an effective capacitive impedance.

21. The RF circuit of claim 2, wherein said at least one series inductor member further includes:
a bond wire.

22. The RF circuit of claim 2, wherein said at least one series inductor member further includes:
a spiral inductor.

23. The RF circuit of claim 2, wherein said at least one series inductor member further includes:
a ribbon wire.

24. The RF circuit of claim 2, wherein said at least one series inductor member further includes:
a coil wire inductor.

25. The RF circuit of claim 2, wherein said at least one series inductor member further includes:
a printed transmission line including an effective inductive impedance.

26. The RF circuit of claim 2, wherein said at least one series inductor member further includes:
a member including an effective inductive impedance.

27. The RF circuit of claim 8, wherein said at least one shunt inductor member further includes:
a bond wire.

28. The RF circuit of claim 8, wherein said at least one shunt inductor member further includes:
a spiral inductor.

29. The RF circuit of claim 8, wherein said at least one shunt inductor member further includes:
a ribbon wire.

30. The RF circuit of claim 8, wherein said at least one shunt inductor member further includes:
a coil wire inductor.

31. The RF circuit of claim 8, wherein said at least one shunt inductor member further includes:
a printed transmission line including an effective inductive impedance.

32. The RF circuit of claim 8, wherein said at least one shunt inductor member further includes:
a member including an effective inductive impedance.

33. An RF circuit comprising:
an input low pass impedance transform network (IL_PITN) having an input and an output; said output of said IL_PITN being connected to a first junction;
an input high pass impedance transform network (IH_PITN) having an input and an output; said input of said IH_PITN being connected to said first junction; said output of said IH_PITN being connected to a second junction;
and
an output high pass impedance transform network (OH_PITN) having an input and an output; said input of said OH_PITN being connected to a third junction;
wherein said RF circuit includes an RF transistor coupled to said second junction and coupled to said third junction, and wherein an input impedance of said RF transistor is matched to an input impedance of said RF circuit;
and wherein an output impedance of said RF transistor is matched to an output impedance of said RF circuit.

34. An RF circuit comprising:
an input high pass impedance transform network (IH_PITN) having an input and an output; said output of said IH_PITN being connected to a first junction;
an output high pass impedance transform network (OH_PITN) having an input and an output; said input of said OH_PITN being connected to a second junction; said output of said OH_PITN being connected to a third junction;
and
an output low pass impedance transform network (OL_PITN) having an input and an output; said input of said OL_PITN being connected to said third junction;
wherein said RF circuit includes an RF transistor coupled to said first junction and coupled to said second junction;
and wherein an input impedance of said RF transistor is matched to an input impedance of said RF circuit;
and wherein an output impedance of said RF transistor is matched to an output impedance of said RF circuit.

35. An RF circuit comprising:
an input high pass impedance transform network (IH_PITN) having an input and an output; said output of said IH_PITN being connected to a first junction;
and
an output high pass impedance transform network (OH_PITN) having an input and an output; said input of said OH_PITN being connected to a second junction;
wherein said RF circuit includes an RF transistor coupled to said first junction and coupled to said second junction;
and wherein an input impedance of said RF transistor is matched to an input impedance of said RF circuit;
and wherein an output impedance of said RF transistor is matched to an output impedance of said RF circuit.

36. A method for optimizing an on-carrier impedance of an RF circuit, said RF circuit including an RF transistor, said method comprising the steps of:
matching an input impedance of said RF transistor to an input impedance of said RF circuit;
and
matching an output impedance of said RF transistor to an output impedance of said RF circuit.

37. The method of claim 36, wherein said RF circuit further includes said RF transistor, and an input high pass impedance transform network (IH_PITN); and wherein said step of matching said input impedance of said RF transistor to said input impedance of said RF circuit further includes the step of:
matching said input impedance of said RF transistor to said input impedance of said RF circuit by using said IH_PITN.

38. The method of claim 36, wherein said RF circuit further includes said RF transistor, an input low pass impedance transform network (IL_PITN), and an input high pass impedance transform network (IH_PITN); and wherein said step of matching said input impedance of said RF transistor to said input impedance of said RF circuit further includes the step of:
matching said input impedance of said RF transistor to said input impedance of said RF circuit by using said IL_PITN and by using said IH_PITN.

39. The method of claim 36, wherein said RF circuit further includes said RF transistor, and an output high pass impedance transform network (OH_PITN); and wherein said step of matching said output impedance of said RF transistor to said output impedance of said RF circuit further includes the step of:
matching said output impedance of said RF transistor to said output impedance of said RF circuit by using said OH_PITN.

40. The method of claim 36, wherein said RF circuit further includes said RF transistor, an output low pass impedance transform network (OL_PITN), and an output high pass impedance transform network (OH_PITN); and wherein said step of matching said output impedance of said RF transistor to said output impedance of said RF circuit further includes the step of:
matching said output impedance of said RF transistor to said output impedance of said RF circuit by using said OH_PITN and by using said OL_PITN.

41. An apparatus for optimizing an on-carrier impedance of an RF circuit; wherein said RF circuit further includes an RF transistor; said apparatus further comprising:
a means for matching an input impedance of said RF transistor to an input impedance of said RF circuit;
and
a means for matching an output impedance of said RF transistor to an output impedance of said RF circuit.
